(19) United States
(12) Patent Application Publication
(10) Pub. No.: US 2026/0303033 A1
(43) Pub. Date: Oct. 1, 2026

(54) SEMICONDUCTOR DEVICE

(71) Applicants: Kosuke YAMAMOTO, Tokyo (JP); Takashi IMAIZUMI, Tokyo (JP); Hitoshi HAGIMORI, Tokyo (JP)

(72) Inventors: Kosuke YAMAMOTO, Tokyo (JP); Takashi IMAIZUMI, Tokyo (JP); Hitoshi HAGIMORI, Tokyo (JP)

(73) Assignee: MITSUMI ELECTRIC CO., LTD., Tokyo (JP)

(21) Appl. No.: 19/557,918

(22) Filed: Mar. 5, 2026

(30) Foreign Application Priority Data
Mar. 26, 2025 (JP) 2025-051902

(51) Int. Cl. H03F 1/30; H03G 1/00

(52) U.S. Cl. CPC H03F 1/304; H03G 1/0088

(57) ABSTRACT

A semiconductor device includes an amplifier circuit including an output terminal and an input terminal coupled to a detection element; an arithmetic circuit coupled to the output terminal of the amplifier circuit; and a control circuit coupled to an output side of the arithmetic circuit. The control circuit is configured to control the amplifier circuit while repeating a control period, switch between a first operating state in which the amplifier circuit outputs an offset voltage, and a second operating state in which the amplifier circuit outputs a voltage obtained by amplifying a voltage input to the input terminal; and perform, within the control period, an operation through the arithmetic circuit after switching the amplifier circuit between the first operating state and the second operating state.

### CROSS-REFERENCE TO RELATED APPLICATIONS

The present application is based on and claims priority to Japanese patent application No. 2025-051902, filed on Mar. 26, 2025, with the Japanese Patent Office, the entire contents of which are hereby incorporated by reference.

### TECHNICAL FIELD

The present disclosure relates to a semiconductor device.

### BACKGROUND

Conventionally, a current detection circuit for converting a current flowing through a load to a voltage and detecting the current has been known. The current detection circuit includes a voltage conversion circuit unit for converting the current flowing through the load into the voltage; an amplification circuit unit including an operational amplifier for amplifying the voltage converted by the voltage conversion circuit unit; a constant current circuit unit including a constant current circuit connected to one input of the operational amplifier; and a current value detection unit for detecting a load current value from the voltage amplified by the amplification circuit unit. The constant current circuit unit shifts an input offset voltage of the operational amplifier in the amplification circuit unit (for example, see Patent Document 1).

### RELATED-ART DOCUMENT

### Patent Document

Patent Document 1: Japanese Unexamined Patent Application Publication No. 2000-166279

### SUMMARY

A semiconductor device according to an embodiment of the present disclosure includes an amplifier circuit including an output terminal and an input terminal coupled to a detection element; an arithmetic circuit coupled to the output terminal of the amplifier circuit; and a control circuit coupled to an output side of the arithmetic circuit. The control circuit is configured to control the amplifier circuit while repeating a control period; switch between a first operating state in which the amplifier circuit outputs an offset voltage, and a second operating state in which the amplifier circuit outputs a voltage obtained by amplifying a voltage input to the input terminal; and perform, within the control period, an operation through the arithmetic circuit after switching the amplifier circuit between the first operating state and the second operating state.

### BRIEF DESCRIPTION OF THE DRAWINGS

FIG. 1 is a diagram showing a configuration example of a motor drive IC 100 according to an embodiment.

FIG. 2 is a block diagram showing a simplified configuration example of the motor drive IC 100.

FIG. 3A is a diagram showing an example of a circuit configuration of an amplifier 110.

FIG. 3B is a diagram showing an example of the circuit configuration of the amplifier 110.

FIG. 4 is a diagram showing an example of periods T1 and T2 during which a first operating state and a second operating state are executed within a PWM period T.

### DETAILED EMBODIMENTS

An output offset voltage of the operational amplifier (amplifier circuit) has temperature drift that changes with temperature. However, since the conventional current detection circuit does not compensate for the temperature drift, the output voltage of the operational amplifier (amplifier circuit) fluctuates when the temperature changes.

An object of the present disclosure is to provide a semiconductor device capable of correcting variations in an output offset voltage of an amplifier circuit due to temperature drift.

Hereinafter, embodiments to which a semiconductor device of the present disclosure is applied will be described.

### Embodiments

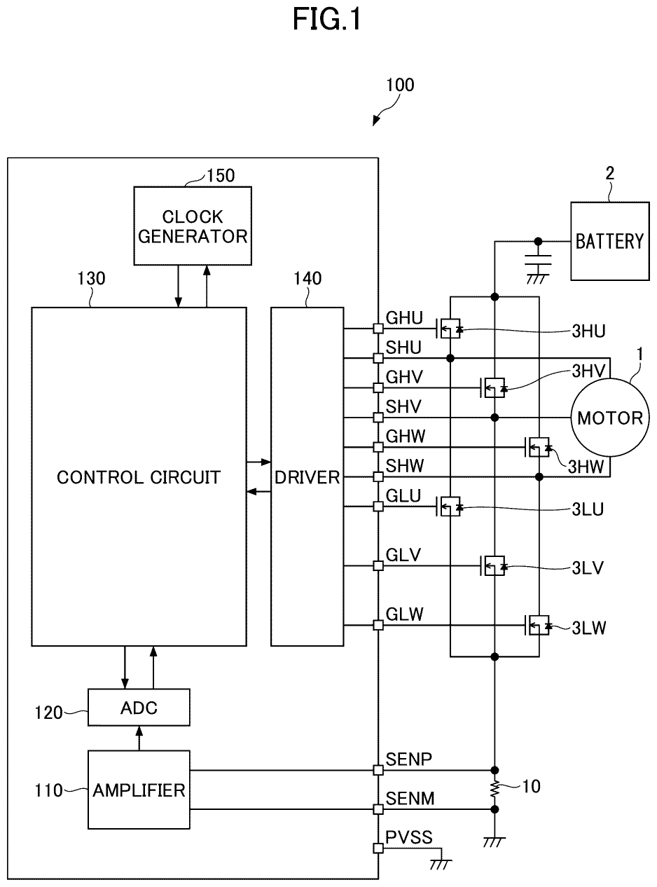

FIG. 1 is a diagram showing a configuration example of a motor drive integrated circuit (IC) 100 according to an embodiment. FIG. 1 shows a motor 1, a battery 2, transistors 3HU, 3LU, 3HV, 3LV, 3HW, and 3LW, a sense resistor 10, and the motor drive IC 100. The motor drive IC 100 is an example of the semiconductor device. The motor 1 is an example of a load. The sense resistor 10 is an example of a detection element.

The motor 1 is a three-phase motor as an example. In the embodiment, a configuration in which the motor 1 is an example of the load will be described, and the load is driven by the motor drive IC 100, which is used as an example of the semiconductor device. The motor 1 is a motor that rotates a cooling fan or the like of a vehicle as an example, and the type of load is not limited to the above example.

The motor 1, the battery 2, the transistors 3HU, 3LU, 3HV, 3LV, 3HW, and 3LW, the sense resistor 10, and the motor drive IC 100 are mounted on the vehicle, for example. A speed command is input to the motor drive IC 100 from a motor drive ECU (Electronic Control Unit) (not shown), and the motor drive IC 100 controls the drive of the motor 1 through the transistors 3HU to 3LW based on the speed command.

The battery 2 is a direct current (DC) power supply and supplies power to the motor 1 via the transistors 3HU to 3LW. The battery 2 also supplies power to the motor drive IC 100, but a power supply path from the battery 2 to the motor drive IC 100 is omitted in FIG. 1.

The transistors 3HU and 3LU are U-phase high-side and low-side transistors. The transistors 3HV and 3LV are V-phase high-side and low-side transistors. The transistors 3HW and 3LW are W-phase high-side and low-side transistors.

The transistors 3HU to 3LW are gate-driven switching elements, each of which has a first main electrode, a second main electrode, and a gate electrode. A specific example of the transistor includes an N-channel field effect transistor (FET) having a drain, a source, and a gate; an insulated gate bipolar transistor (IGBT) having a collector, an emitter, and a gate; or the like. A specific example of the FET includes a metal oxide semiconductor field effect transistor (MOSFET) or the like. The drain or the collector is an example of the first main electrode. The source or the emitter is an example of the second main electrode. FIG. 1 illustrates a case where the transistors 3HU to 3LW are N-channel MOSFETs.

### Motor Drive IC 100

The motor drive IC 100 includes an amplifier 110, an analog-to-digital converter (ADC) 120, a control circuit 130, a driver 140, and a clock generator 150. The amplifier 110 is an example of an amplifier circuit. The ADC 120 is an example of an arithmetic circuit, specifically an analog-to-digital converter circuit. The motor drive IC 100 is configured as one integrated circuit (IC) package, for example. The amplifier 110 and the ADC 120 are configured as one sensor circuit, for example.

The motor drive IC 100 has terminals GHU, GLU, GHV, GLV, GHW, GLW, SHU, SHV, SHW, SENP, and SENM. The terminals GHU, GLU, GHV, GLV, GHW, GLW, SHU, SHV, and SHW are connected to the driver 140 inside the motor drive IC 100. The terminals SENP and SENM are connected to the amplifier 110 inside the motor drive IC 100.

The terminal GHU is connected to the gate of the transistor 3HU outside the motor drive IC 100, and outputs a gate drive signal output from the driver 140. Similarly, the terminals GLU, GHV, GLV, GHW, and GLW are connected to the gates of the transistors 3LU, 3HV, 3LV, 3HW, and 3LW outside the motor drive IC 100, respectively, and output respective gate drive signals output from the driver 140.

The terminals SHU, SHV, and SHW are connected to the sources of the transistors 3HU, 3HV, and 3HW outside the motor drive IC 100, respectively. The source voltages of the transistors 3HU, 3HV, and 3HW are taken into the driver 140 through the terminals SHU, SHV, and SHW, respectively, and are used for generating gate drive signals.

The terminals SENP and SENM are connected to respective ends of the sense resistor 10. More specifically, the terminal SENP is connected to a high-potential side terminal (upper terminal in FIG. 1) of the sense resistor 10, and the terminal SENM is connected to a low-potential side terminal (lower terminal in FIG. 1) of the sense resistor 10.

A high-potential side terminal of the sense resistor 10 is connected to the second main electrodes (sources of the N-channel MOSFET) of the transistors 3LU, 3LV, and 3LW. A low-potential side terminal of the sense resistor 10 is connected to a ground. The ground is an example of a reference potential point. In this arrangement, a current obtained by combining three-phase currents flows through the sense resistor 10 from lead wires for the U-phase, W-phase, and V-phase of the motor 1, respectively, and the current flows through the transistors 3LU, 3LV, and 3LW. The sense resistor 10 is an element for detecting the current flowing through windings of the motor 1.

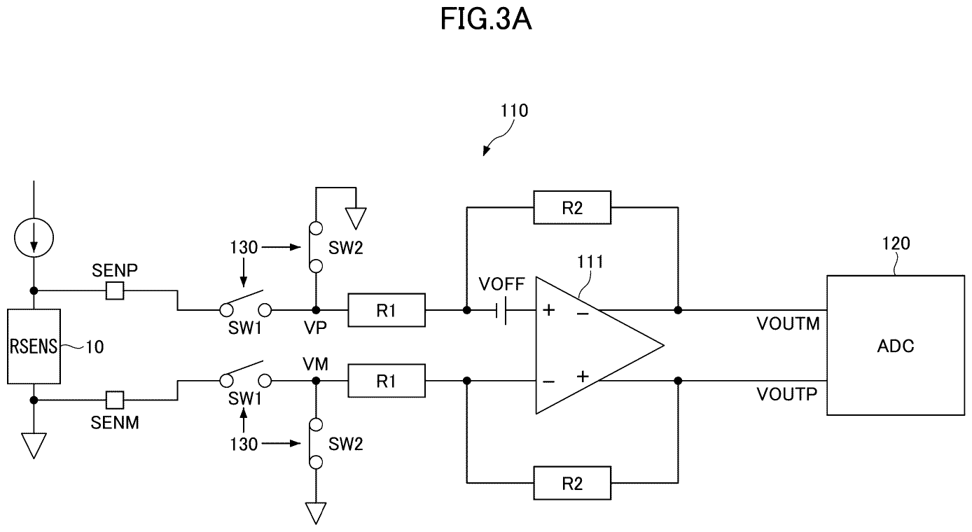

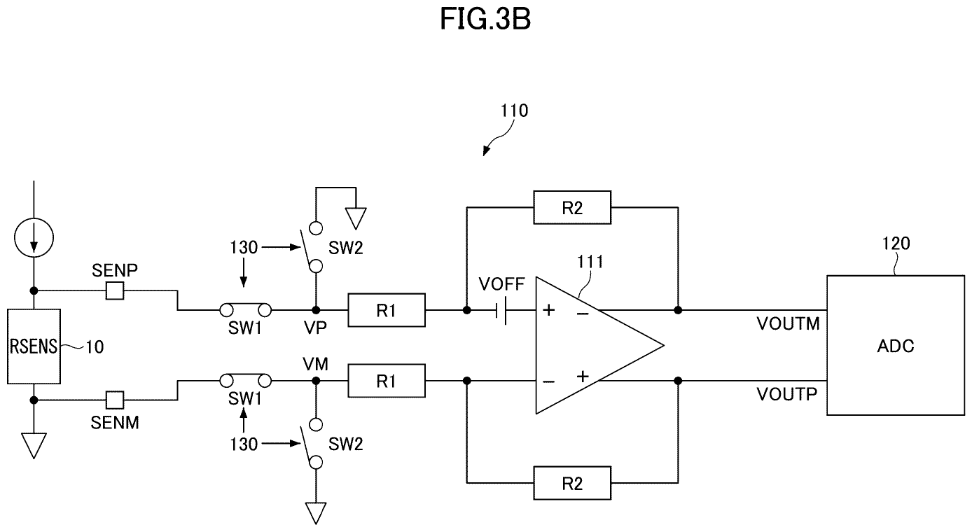

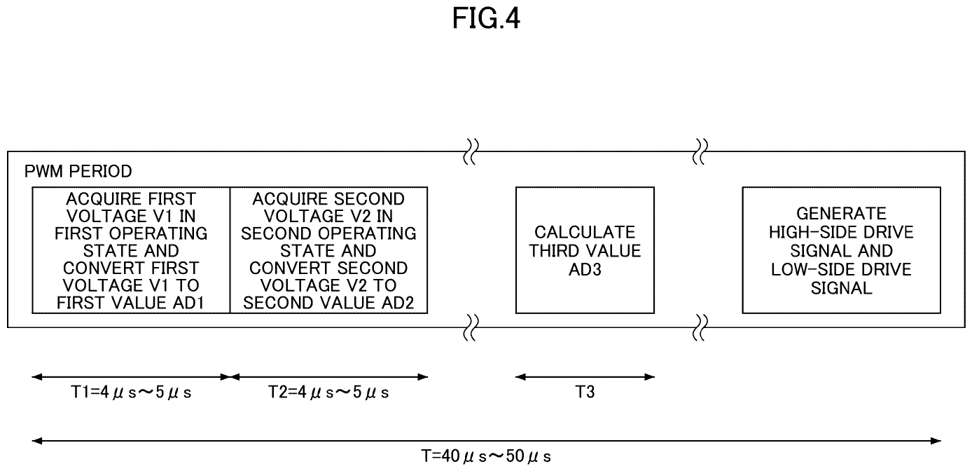

As a result, a voltage corresponding to the current obtained by combining the three-phase currents of the motor 1 is supplied to the amplifier 110 via the terminals SENP and SENM. The amplifier 110 amplifies the input voltage and outputs the amplified voltage to the ADC 120. The detailed configuration and operation of the amplifier 110 will be described later with reference to FIGS. 3A, 3B, and 4.

For example, when the motor 1 is a motor for rotating a cooling fan or the like of the vehicle, a current on the order of several amperes flows through the sense resistor 10. In order to convert such a current into a voltage, a resistor having a low resistivity on the order of several milliohms is used as the sense resistor 10. This is because if power consumption of the sense resistor 10 is large, the rated power of the sense resistor 10 is exceeded.

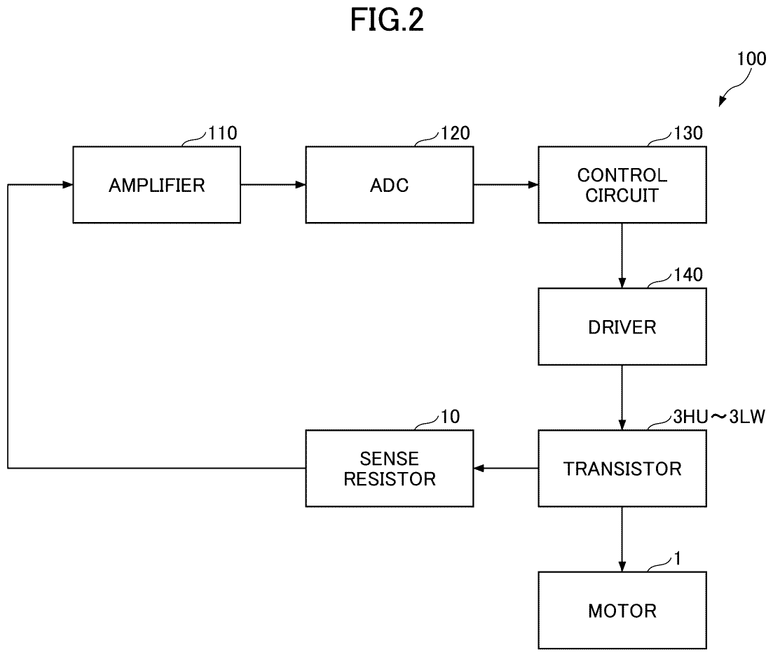

Hereinafter, the operation of the motor drive IC 100 will be described with reference to FIG. 2 in addition to FIG. 1. FIG. 2 is a block diagram showing a simplified example of the configuration of the motor drive IC 100. FIG. 2 shows the motor 1, the transistors 3HU to 3LW, the sense resistor 10, and the motor drive IC 100.

The ADC 120 digitally converts the voltage input from the amplifier 110 and outputs the converted result to the control circuit 130. The voltage input from the amplifier 110 is a voltage representing a current value of the current obtained by combining the three-phase currents of the motor 1. The control circuit 130 generates high-side drive signals and low-side drive signals in which a duty ratio is set by pulse width modulation (PWM), and outputs these signals to the driver 140.

The ADC 120 digitally converts the output voltage in the first operating state of the amplifier 110 and the output voltage in the second operating state of the amplifier 110, for each PWM period (PWM cycle). The PWM period is an example of a control period. The first operating state and the second operating state of the amplifier 110 are switched by the control circuit 130. Details of the switching will be described later with reference to FIGS. 3A, 3B, and 4.

As an example, the control circuit 130 operates in response to a clock input from the clock generator 150. As an example, the control circuit 130 determines the PWM duty ratio for each PWM period, based on a speed command input from the motor drive ECU and a voltage value input from the ADC 120, and then generates high-side drive signals and low-side drive signals in PWM format. The control circuit 130 outputs the high-side drive signals and the low-side drive signals to the driver 140 for each PWM period. The high-side drive signals and the low-side drive signals are signals having a PWM duty ratio.

The driver 140 generates gate drive signals based on the high-side drive signals and the low-side drive signals, and outputs the gate drive signals to the gates of the transistors 3HU, 3LU, 3HV, 3LV, 3HW, and 3LW via the terminals GHU, GLU, GHV, GLV, GHW, and GLW, respectively.

In this arrangement, the motor 1 is driven by the motor drive IC 100.

### Detailed Configuration and Operation of Amplifier 110

FIGS. 3A and 3B are diagrams showing an example of the circuit configuration of the amplifier 110. FIG. 3A shows the amplifier 110 in the first operating state, and FIG. 3B shows the amplifier 110 in the second operating state. The difference between FIGS. 3A and 3B is in the on and off states of switches SW1 and SW2. In FIG. 3A, as an example, two switches SW1 are turned off (open), and two switches SW2 are turned on (closed). In FIG. 3B, as an example, the two switches SW1 are turned on (closed), and the two switches SW2 are turned off (open). First, the configuration of the amplifier 110 will be described with reference to FIG. 3A. The voltage values at the terminals SENP and SENM are represented by SENP and SENM, respectively.

### Amplifier 110

The amplifier 110 has the two switches SW1, the two switches SW2, two resistors R1, two resistors R2, and a fully differential operational amplifier 111. The fully differential operational amplifier 111 is an example of a differential amplifier. Each switch SW1 is an example of a first switch, and each switch SW2 is an example of a second switch. The resistors R1 and R2 are resistors having resistance values R1 and R2, respectively.

FIG. 3A shows the sense resistor 10, the terminals SENP and SENM, the ADC 120, and the amplifier 110. A current source disposed upstream of the sense resistor 10 corresponds to the transistors 3LU, 3LV, and 3LW. The sense resistor 10 is a resistor having the resistance value RSENS.

Two input terminals of the amplifier 110 are connected to the terminals SENP and SENM, respectively. In this arrangement, the two input terminals of the amplifier 110 are connected to respective ends of the sense resistor 10.

The fully differential operational amplifier 111 has a first input terminal (+), a second input terminal (−), a first output terminal (+), and a second output terminal (−). One switch SW1 (upper side in FIG. 3A) is connected between one input terminal of the amplifier 110 (upper side in FIG. 3A) and the first input terminal (+). The other switch SW1 (lower side in FIG. 3A) is connected between the other input terminal of the amplifier 110 (lower side in FIG. 3A) and the second input terminal (−).

One resistor R1 is connected between the one switch SW1 and the first input terminal (+). The other resistor R1 is connected between the other switch SW1 and the second input terminal (−). One resistor R2 (upper side in FIG. 3A) is connected between the first input terminal (+) and the second output terminal (−) of the fully differential operational amplifier 111. The other resistor R2 (lower side in FIG. 3A) is connected between the second input terminal (−) and the first output terminal (+) of the fully differential operational amplifier 111.

The output voltage at the second output terminal (−) of the fully differential operational amplifier 111 is represented by VOUTM. The output voltage at the first output terminal (+) of the fully differential operational amplifier 111 is represented by VOUTP. The output voltages VOUTP and VOUTM are differential output voltages of the amplifier 110. The first output terminal (+) and the second output terminal (−) are two output terminals of the amplifier 110 and are respectively connected to two input terminals of the ADC 120. The first output terminal (+) and the second output terminal (−) of the fully differential operational amplifier 111 may output the output voltages VOUTP and VOUTM through the amplifier.

A node VP is a connection point between one switch SW1 and one resistor R1, and one end of one switch SW2 (upper side in FIG. 3A) is connected to the node VP. A node VM is a connection point between the other switch SW1 and the other resistor R1, and one end of the other switch SW2 (lower side in FIG. 3A) is connected to the node VM. The node VP is an example of a first node, and the node VM is an example of a second node. The voltages at the nodes VP and VM are represented by VP and VM.

The other end of one switch SW2 is connected to the ground, for example. That is, one switch SW2 is connected between the node VP and the ground. The other end of the other switch SW2 is connected to the ground, for example. That is, the other switch SW2 is connected between the node VM and the ground. The two switches SW1 and the two switches SW2 are constituted by, for example, transistors or the like, and are controlled to switch on and off by the control circuit 130. In the embodiment, the other end of each switch SW2 is preferably set to the same voltage.

The gain of the fully differential operational amplifier 111 is represented by the ratio (R2/R1) of the resistance values of the resistors R1 and R2. Since the voltage input to the amplifier 110 via the terminals SENP and SENM is very low, the gain of the fully differential operational amplifier 111 is set high in order to use the ADC 120 at full scale. An offset of the output voltage (output offset) of the fully differential operational amplifier 111 is obtained by multiplying the offset of the input voltage (input offset) by the gain. Therefore, even if the input offset is small, the output offset becomes large when the gain is high. Further, the output offset has temperature drift.

The gain of the fully differential operational amplifier 111 can be appropriately set in accordance with the application of the motor 1. For example, when the motor 1 is a motor for rotating a cooling fan or the like of a vehicle, the gain is 100 times or greater.

### Method for Correcting Variations in Output Offset Due to Temperature Drift

In order to correct variations in the output offset of the fully differential operational amplifier 111 due to the temperature drift, the motor drive IC 100 switches the amplifier 110 between the first operating state shown in FIG. 3A and the second operating state shown in FIG. 3B, for each PWM period.

### First Operating State

In the first operating state, as shown in FIG. 3A, for example, two switches SW1 are turned off (open) and two switches SW2 are turned on (closed). In this state, nodes VP and VM are disconnected from terminals SENP and SENM by the two switches SW1 and are connected to the ground by the two switches SW2. Therefore, a differential input voltage (VP−VM) at the first input terminal (+) and the second input terminal (−) of the fully differential operational amplifier 111 becomes 0 V.

Further, the differential output voltage (VOUTP−VOUTM) of the amplifier 110 becomes 0 V in an ideal state, but actually becomes VOFF×gain, due to an input offset VOFF. In other words, VOUTP−VOUTM=VOFF×gain.

The differential output voltage (VOFF×gain) in such a first operating state is defined as a first voltage V1, that is, V1=VOFF×gain. The first voltage V1 is digitally converted by the ADC 120 into a first value AD1, which represents AD1=VOFF×gain as a digital value. The gain is given by R2÷R1(=R2/R1).

In the first operating state as described above, the fully differential operational amplifier 111 performs an operation to amplify the input offset VOFF in a state where the two switches SW1 are turned off and the two switches SW2 are turned on by the control circuit 130.

### Second Operating State

In the second operating state, as shown in FIG. 3B, for example, the two switches SW1 are turned on (closed) and the two switches SW2 are turned off (open). In this state, the nodes VP and VM are connected to the terminals SENP and SENM by the two switches SW1 and are disconnected from the ground by the two switches SW2. Therefore, a voltage (SENP SENM) obtained by converting the current flowing through the sense resistor 10 is input to the fully differential operational amplifier 111. That is, in an ideal second operating state without the input offset VOFF, the differential input voltage (VP−VM) of the first input terminal (+) and the second input terminal (−) becomes (SENP−SENM).

However, since the input offset VOFF is actually obtained, the input voltage of the fully differential operational amplifier 111 becomes a voltage (SENP−SENM +VOFF) obtained by adding the input offset VOFF to the differential input voltage (SENP−SENM). Therefore, the differential output voltage (VOUTP−VOUTM) of the amplifier 110 in the second operating state becomes (SENP−SENM+VOFF)×gain. That is, VOUTP−VOUTM=(SENP−SENM+VOFF)×gain.

The differential output voltage {(SENP−SENM+VOFF)×gain} in the second operating state is defined as the second voltage V2, that is, V2=(SENP−SENM+VOFF)×gain. The second voltage V2 is digitally converted by the ADC 120 into a second value AD2. The second value AD2 is a digital value and represents (SENP−SENM+VOFF)×gain.

The second operating state as described above is a state in which the fully differential operational amplifier 111 performs an operation of amplifying a voltage (SENP−SENM+VOFF) obtained by adding the input offset VOFF to the differential input voltage (SENP−SENM) in a state in which the two switches SW1 are turned on and the two switches SW2 are turned off by the control circuit 130.

### Calculation of Third Value AD3

The control circuit 130 obtains the first value AD1 and the second value AD2 by switching the two switches SW1 and the two switches SW2, for each PWM period.

The control circuit 130 calculates a third value AD3 by subtracting the first value AD1 from the second value AD2 using the first value AD1 and the second value AD2 that are obtained in each PWM period. That is, AD3=AD2−AD1={(SENP−SENM+VOFF)×gain}−(VOFF×gain)=(SENP−SENM)×gain.

Since the third value AD3 calculated in this manner does not include a term of the input offset VOFF, the third value AD3 can be used for correction such that the output offset of the amplifier 110 is substantially eliminated.

For example, the PWM period is about 40 μs to 50 μs. For example, a time period required for acquiring the first voltage V1 and digitally converting the first voltage V1 into the first value AD1 in the first operating state is about 4 μs to 5 μs. For example, a time period required for acquiring the second voltage V2 and digitally converting the second voltage V2 into the second value AD2 in the second operating state is about 4 μs to 5 μs.

A time period required for the control circuit 130 to calculate the third value AD3 by subtracting the first value AD1 from the second value AD2 is equal to or less than a time period of each of the first operating state and a time period in the second operating state.

In this arrangement, in each PWM period, the amplifier 110 can be switched between the first operating state and the second operating state, the ADC 120 can digitally convert the first voltage V1 into the first value AD1, the ADC 120 can digitally convert the second voltage V2 into the second value AD2, and the third value AD3 can be calculated.

For example, if the third value AD3 is calculated by switching the amplifier 110 between the first operating state and the second operating state within a short period such as a PWM period, the temperature hardly changes during the acquisition of the first voltage V1 and the second voltage V2 even when the amplifier 110 is used in an environment in which the temperature changes due to heat generation of the motor 1 or the like. Therefore, it is possible to perform correction to substantially eliminate variations in the output offset of the fully differential operational amplifier 111 due to temperature drift.

FIG. 4 is a diagram showing an example of periods T1 and T2 within a PWM period T, where the first operating state and the second operating state are performed, and the first voltage V1 is digitally converted into the first value AD1, and the second voltage V2 is digitally converted into the second value AD2. FIG. 4 also shows a period T3 during which the third value AD3 is calculated, and a period during which high-side drive signals and low-side drive signals are generated and output.

As shown in FIG. 4, if the amplifier 110 is sequentially switched between the first operating state (period T1) and the second operating state (period T2) in an initial stage of the PWM period T (about 40 μs to 50 μs), the temperature change of the amplifier 110 during the acquisition of the first voltage V1 and the second voltage V2 is negligible. As described above, by sequentially switching the amplifier 110 between the first operating state and the second operating state within one PWM period, it is possible to effectively correct variations in the output offset of the fully differential operational amplifier 111 due to temperature drift.

For example, when the motor 1 is a motor for rotating a cooling fan or the like of a vehicle, a driving state of the motor 1 may change from time to time, so that the temperature of the amplifier 110 arranged near the motor 1 may change rapidly. Even in such an application, the motor drive IC 100 can correct the output offset voltage of the amplifier 110 having the fully differential operational amplifier 111, such that the variations due to the temperature drift are substantially eliminated.

As shown in FIG. 4, after the first voltage V1 is obtained during the period T1, digital conversion is performed by the ADC 120 to obtain the first value AD1. After obtaining the second voltage V2 during the period T2, digital conversion is performed by the ADC 120 to obtain the second value AD2.

After obtaining the first value AD1 and the second value AD2, the control circuit 130 calculates the third value AD3 during the period T3 after the period T2. After the period T3, the control circuit 130 generates the high-side drive signals and the low-side drive signals with the set PWM duty ratio and outputs these signals to the driver 140.

In this arrangement, the process from obtaining the first voltage V1 to generating and outputting the high-side drive signals and the low-side drive signals is repeatedly executed for each PWM period.

Although FIG. 4 shows a switching method for sequentially switching the amplifier 110 in the order of the first operating state and the second operating state within one PWM period, the amplifier 110 may be sequentially switched in the order of the second operating state and the first operating state. Even if the order of the first operating state and the second operating state is reversed, the first voltage V1 and the second voltage V2 can be obtained while the temperature of the amplifier 110 hardly changes.

FIG. 4 shows the switching method for successively switching the amplifier 110 between the first operating state and the second operating state within one PWM period. However, within one PWM period, another process in which variations due to temperature drift hardly occur may be inserted between switching the amplifier 110 to the first operating state and switching the amplifier 110 to the second operating state. This is because the first voltage V1 and the second voltage V2 can be obtained in a state in which variations due to temperature drift hardly occur within one PWM period.

When the temperature change of the amplifier 110 is small or the speed of temperature change is slow, switching the amplifier 110 to the first operating state to acquire the first voltage V1 and the first value AD1, and switching the amplifier 110 to the second operating state to acquire the second voltage V2 and the second value AD2 and to calculate the third value AD3, may be separately performed in two PWM periods with one or more PWM periods interposed between the two PWM periods.

### Effects

The motor drive IC 100 includes an amplifier 110 including an input terminal connected to a sense resistor 10; an ADC 120 connected to an output terminal of the amplifier 110; and a control circuit 130 connected to an output side of the ADC 120 and configured to control the amplifier 110 while repeating a control period. The control circuit 130 can switch between a first operating state, in which the amplifier 110 outputs an offset voltage, and a second operating state in which the amplifier 110 outputs a voltage obtained by amplifying a voltage input to the input terminal. The control circuit 130 performs an operation through the arithmetic circuit after switching the amplifier 110 between the first operating state and the second operating state within a control period. In this arrangement, an output offset, and an output obtained by amplifying the input voltage can be obtained while variations in the output offset due to temperature drift hardly occur.

As a result, it is possible to provide a semiconductor device (motor drive IC 100) capable of correcting an output offset voltage of the amplifier circuit (amplifier 110) to substantially eliminate variations due to temperature drift. Further, since the output offset and the output obtained by amplifying the input voltage can be obtained while the variations in the output offset due to the temperature drift hardly occur, correction can be performed such that the influence of individual differences in the offset voltage of the amplifier circuit (amplifier 110) is substantially eliminated.

Further, the calculation by the control circuit 130 may successively use the first value AD1, obtained by digitally converting the offset voltage (output offset) obtained in the first operating state by the ADC 120, and the second value AD2, obtained by digitally converting the output of the amplifier 110 obtained in the second operating state by the ADC 120, and may output the third value AD3 obtained by subtracting the first value AD1 from the second value AD2. By performing the first operating state and the second operating state sequentially, a temperature variation between the first operating state and the second operating state can be substantially eliminated. Since the third value AD3 obtained by subtracting the first value AD1 from the second value AD2 is obtained under conditions where the temperature variation between the first operating state and the second operating state is substantially eliminated, the influence of the temperature drift can be suppressed, and a load can be accurately controlled.

Further, a first operating state may include calculating the first value AD1 by digitally converting the offset voltage, and a second operating state may include calculating the second value AD2 by digitally converting the amplified voltage. The first value AD1 and the second value AD2 can be reliably calculated in the first operating state and the second operating state.

Further, the control circuit 130 may sequentially switch the amplifier 110 from the first operating state to the second operating state for each control period. Here, the term “sequentially” means that the second operating state is performed after the first operating state, and another operation for a shorter time period than the first operating state and the second operating state may be interposed between the first operating state and the second operating state. Since the switching between the first operating state and the second operating state is sequentially performed, it is possible to provide a semiconductor device (motor drive IC 100) in which variations in the output offset due to temperature drift are substantially negligible even when the semiconductor device is used in an environment with significant temperature change, and variations in the output offset voltage of the amplifier circuit (amplifier 110) due to temperature drift can be more effectively corrected.

Further, the sense resistor 10 may be an element for detecting a current flowing through a winding of the motor 1, the voltage input to an input terminal of the amplifier 110 may be a voltage across the sense resistor 10, and a control period may be a PWM period during which the motor 1 is driven. If a period is as short as the PWM period, variations in an output offset due to temperature drift hardly occur. An output offset and an output obtained by amplifying the input voltage can be obtained within a period that is the PWM period in which the variations in the output offset due to the temperature drift hardly occur.

Further, the amplifier 110 may include a fully differential operational amplifier 111, a switch SW1 connected between an input terminal of the amplifier 110 and an input terminal of the fully differential operational amplifier 111, and a switch SW2 connected between a node VP, which is between the input terminal of the fully differential operational amplifier 111 and the switch SW1, and a ground. When the switch SW2 is turned on and the switch SW1 is turned off, the node VP can be set to a ground potential, and when the switch SW1 is turned on and the switch SW2 is turned off, an input voltage can be amplified.

The control circuit 130 may turn the switch SW1 off and turn the switch SW2 on in the first operating state, and may turn the switch SW1 on and turn the switch SW2 off in the second operating state. A node VP can be set to the ground potential in the first operating state, and the input voltage can be amplified in the second operating state.

Further, the amplifier 110 has two input terminals, and the two input terminals are connected to respective ends of the sense resistor 10. Also, the amplifier 110 has a fully differential operational amplifier 111 having a first input terminal (+) and a second input terminal (−); two switches SW1; and two switches SW2. One of the two switches SW1 is connected between one of the two input terminals and the first input terminal (+), the other switch SW1 is connected between the other input terminal and the second input terminal (−), one of the two switches SW2 is connected between a node VP, which is between the first input terminal (+) and one of the two switches SW1, and a ground, and the other switch SW2 may be connected between a node VM, which is between the second input terminal (−) and the other switch SW1, and the ground. When the two switches SW2 are turned on and the two switches SW1 are turned off, the nodes VP and VM can be set to the ground potential. When the two switches SW1 are turned on and the two switches SW2 are turned off, the differential input voltages input to the first input terminal (+) and the second input terminal (−) can be amplified.

Further, the amplifier 110 may turn two switches SW1 off and turn two switches SW2 on in the first operating state, and turn the two switches SW1 on and turn the two switches SW2 off in the second operating state. The nodes VP and VM can be set to a ground potential in the first operating state, and the differential input voltage can be amplified in the second operating state.

Although the semiconductor device according to the embodiments of the present disclosure has been described above, the present disclosure is not limited to the embodiments specifically disclosed, and various modifications and modifications may be made without departing from the scope of the present disclosure. As the amplifier 110, a fully differential operational amplifier 111 is used, but an operational amplifier to which a reference voltage is input can also be used.

In the present disclosure, a semiconductor device capable of correcting variations in an output offset voltage of an amplifier circuit due to temperature drift can be provided.

What is claimed is:

1. A semiconductor device comprising:
an amplifier circuit including an output terminal and an input terminal coupled to a detection element;
an arithmetic circuit coupled to the output terminal of the amplifier circuit; and
a control circuit coupled to an output side of the arithmetic circuit and configured to:
control the amplifier circuit while repeating a control period,
switch between:
a first operating state in which the amplifier circuit outputs an offset voltage, and
a second operating state in which the amplifier circuit outputs a voltage obtained by amplifying a voltage input to the input terminal, and
perform, within the control period, an operation through the arithmetic circuit after switching the amplifier circuit between the first operating state and the second operating state.

2. The semiconductor device according to claim 1, wherein the control circuit is configured to perform the operation to:
acquire a first value obtained by digitally converting, by the arithmetic circuit, the offset voltage obtained in the first operating state, and a second value obtained by digitally converting, by the arithmetic circuit, an output of the amplifier circuit obtained in the second operating state, and
output a third value obtained by subtracting the first value from the second value.

3. The semiconductor device according to claim 2, wherein the first operating state includes digitally converting the offset voltage to calculate the first value, and the second operating state includes digitally converting the amplified voltage to calculate the second value.

4. The semiconductor device according to claim 1, wherein the control circuit is configured to sequentially switch the amplifier circuit from the first operating state to the second operating state within the control period.

5. The semiconductor device according to claim 1, wherein the detection element is an element configured to detect a current flowing through a winding in a motor,
wherein the voltage input to the input terminal of the amplifier circuit corresponds to a voltage across the detection element, and
wherein the control period is a pulse width modulation (PWM) period during which the motor is driven.

6. The semiconductor device according to claim 1, wherein the amplifier circuit includes:
a differential amplifier including an input terminal,
a first switch coupled between the input terminal of the amplifier circuit and the input terminal of the differential amplifier, and
a second switch coupled between a first node and a reference potential point, the first node being disposed between the input terminal of the differential amplifier and the first switch.

7. The semiconductor device according to claim 6, wherein the control circuit is configured to:
turn off the first switch and turn on the second switch in the first operating state, and
turn on the first switch and turn off the second switch in the second operating state.

8. The semiconductor device according to claim 1, wherein the amplifier circuit includes:
two input terminals coupled to respective ends of the detection element,
a differential amplifier including a first input terminal and a second input terminal,
two first switches, and
two second switches,
wherein one of the two first switches is coupled between one of the two input terminals and the first input terminal,
wherein another first switch is coupled between another input terminal and the second input terminal,
wherein one of the two second switches is coupled between a first node and a reference potential point, the first node being disposed between the first input terminal and the one first switch, and
wherein another second switch is coupled between a second node and the reference potential point, the second node being disposed between the second input terminal and the another first switch.

9. The semiconductor device according to claim 8, wherein the amplifier circuit is configured to:
turn off the two first switches and turn on the two second switches in the first operating state, and
turn on the two first switches and turn off the two second switches in the second operating state.
